(19) United States
(12) Patent Application Publication
(10) Pub. No.: US 2026/0063374 A1
(43) Pub. Date: Mar. 5, 2026

(54) THREE-DIMENSIONAL HEAT CONDUCTING STRUCTURE AND MANUFACTURING METHOD THEREOF

(71) Applicant: PURPLE CLOUD DEVELOPMENT PTE. LTD., Singapore (SG)

(72) Inventors: LEILEI LIU, Hui Zhou City (CN); XIONG ZHANG, Hui Zhou City (CN); JIAN-JIA HUANG, Taipei City (TW)

(73) Assignee: PURPLE CLOUD DEVELOPMENT PTE. LTD., Singapore (SG)

(21) Appl. No.: 19/259,185

(22) Filed: Jul. 3, 2025

Related U.S. Application Data
(60) Provisional application No. 63/689,272, filed on Aug. 30, 2024.

(51) Int. Cl. F28D 15/02; F28D 15/04

(52) U.S. Cl. CPC F28D 15/0283; F28D 15/04; F28F 2235/00; F28F 2275/067

(57) ABSTRACT

A three-dimensional heat conducting structure includes a vapor chamber that has a casing with at least one through hole and is in fluid communication with an interior of the casing. At least one heat pipe having an open end that is inserted into the through hole and is in fluid communication with the interior of the casing. Further, a rim that is disposed on an outer surface of the vapor chamber, wherein gaps between the rim and the heat pipe are sealed by laser welding, and a welding ring is soldered to further secure the connection between the heat pipe and the vapor chamber.

### CROSS-REFERENCE TO RELATED APPLICATIONS

This application is a non-provisional of and claims priority under 35 U.S.C. § 119 to U.S. Provisional Application No. 63/689,272, filed Aug. 30, 2024, the contents of each are hereby incorporated by reference in their entirety.

### FIELD OF THE INVENTION

The present disclosure relates to a heat conducting device, and in particularly to a three-dimensional heat conducting structure and its manufacturing method.

### BACKGROUND

In a conventional heat conducting structure, the heat pipe is combined with the vapor chamber using conventional soldering techniques. However, by doing so, the melted solder may overflow to the undesired combining place as well as other positions such as the interior of vapor chamber, influencing the combined effect of the soldering and resulting in appearance defects and a drop in production yield.

As the convention soldering techniques in the related art, it discloses a support ring that can be placed on either the heat pipe or a hole of the vapor chamber. Furthermore, a solder is arranged around the top of the support ring after the heat pipe and vapor chamber have been joined. A soldering process would then be applied to secure a strong connection via the support ring, which provides a supporting force for the heat pipe and vapor chamber combination.

However, when the heat pipe is placed into the through hole of the vapor chamber, gaps may form between the heat pipe and a rim that surrounds the through hole. The melted welding ring and its solder have a high fluidity due to their relatively low melting points. As a result, the holes allow the melted welding ring and its solder to flow into the vapor chamber.

### SUMMARY

The present disclosure presents a solution to the concerns outlined above. The heat pipe and the vapor chamber are first joined by a laser welding technique, eliminating gaps between the heat pipe and the edge of the vaper chamber hole. After the welding ring is placed on the outer surface of the heat pipe to enclose a rim that is formed around the periphery of the through hole, a soldering process is used to ensure a secure connection between the heat pipe and the vapor chamber. As there is no or little gaps between the heat pipe and the edge of the vaper chamber hole, it could obstruct the melted welding ring and its solder from entering the vapor chamber.

To achieve the abovementioned advantages, the present disclosure provides a three three-dimensional heat conducting structure that includes a vapor chamber having a casing and at least one through hole that is formed on the casing and is in fluid communication with an interior of the casing, at least one heat pipe having an open end that is inserted into the through hole and is in fluid communication with the interior of the casing, and a rim that is formed around a periphery of the through hole and is protruded from an outer surface of the vapor chamber, wherein gaps between the rim and the heat pipe are sealed by laser welding, and a welding ring is soldered to further secure the connection between the heat pipe and the vapor chamber.

In some embodiments, the vapor chamber further includes a capillary structure and a cooling fluid that are arranged in the interior of the casing.

In some embodiments, the welding ring is made of metal, alloy or heat-resistant non-metal material.

In some embodiments, the soldered welding ring stays between the vapor chamber and the heat pipe without overflowing to the interior of the vapor chamber.

In some embodiments, the welding ring encloses the rim before being soldered.

In some embodiments, a secure bond is formed between the rim the heat pipe after the laser welding is applied solely on the gaps between the heat pipe and the rim.

According to one embodiment of the present disclosure, a manufacturing method of a three-dimensional heat conducting structure includes forming a vapor chamber that includes a casing with at least one through hole, forming at least one heat pipe that has an open end, and inserting the open end into the through hole so that the heat pipe and vapor chamber are in fluid communication, applying laser welding process to gaps between the heat pipe and a rim, placing a welding ring on a joint position of the heat pipe and the vapor chamber so that the welding ring can enclose the rim, and applying a welding process to solder the welding ring to secure the connection between the heat pipe and the vapor chamber.

### BRIEF DESCRIPTION OF THE DRAWINGS

Aspects of the present disclosure can be understood from the following detailed description when read with the accompanying Figures. It is noted that, in accordance with the standard practice in the industry, various features are not drawn to scale. In fact, the dimensions of the various features may be increased or reduced for clarity of discussion.

FIG. 1 shows a flowchart of a method for forming a three-dimensional heat conducting structure.

FIG. 2-6 show a manufacturing process for forming the three-dimensional heat conducting structure.

FIG. 3A is a cross-sectional view showing the gaps in FIG. 3 in relative detail.

FIG. 4A is an enlarged square portion of FIG. 4.

### DETAILED DESCRIPTION

Detailed descriptions and technical contents of the present invention are illustrated below in conjunction with the accompanying drawings. However, it is to be understood that the descriptions and the accompanying drawings disclosed herein are merely illustrative and exemplary and not intended to limit the scope of the present invention.

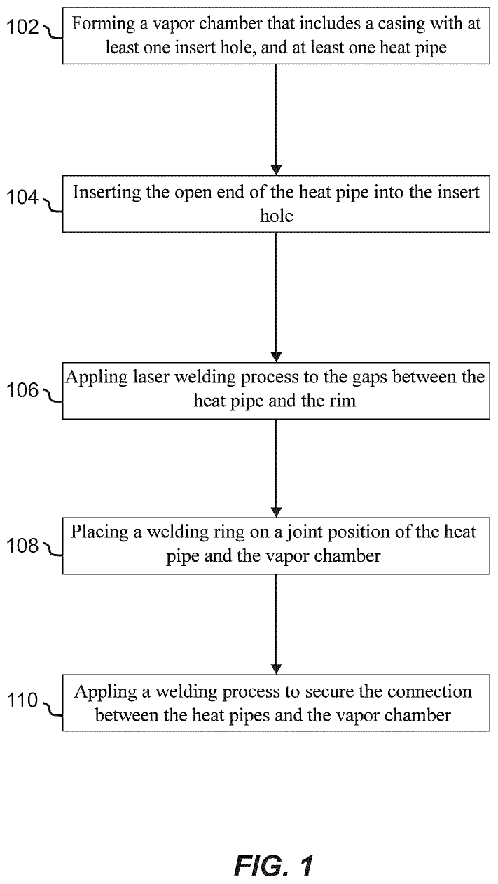

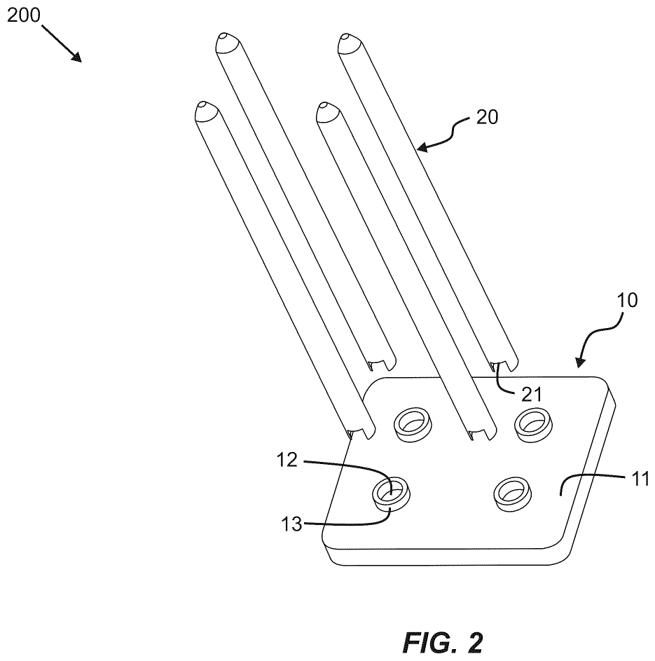

FIG. 1 is a flowchart of an exemplary method 100 for forming a three-dimensional heat conducting structure 200, according to some embodiments of the present disclosure. FIG. 2-6 show an exemplary manufacturing process for forming the three-dimensional heat conducting structure 200.

Referring to FIG. 1, method 100 starts at step 102, in which a vapor chamber 10 and at least one heat pipe 20 are formed as shown in FIG. 2. The heat conducting structure 200 in FIG. 2 includes a vapor chamber 10 and at least one heat pipe 20. The vapor chamber 10 includes a casing 11, and at least one through hole 12 that is formed on the casing 11 and is communicated with the interior of the casing 11. At step 102, in one embodiment, the rim 13 is formed around the periphery of the through hole 12 and is protruded from an outer surface of the vapor chamber 10. In another embodiment, the rim 13 can be welded to the surface of the vapor chamber 10, surrounding the periphery of the through hole 12. The rim 13 is designed to improve the precision and alignment of inserting the heat pipe 20 into the through hole 12 of the vapor chamber 10. The rim 13 ensures an optimal fit and combination between the heat pipe 20 and the vapor chamber 10 by providing a better positioning effect. This enhanced positioning leads to an improved mechanical stability and thermal performance, which ultimately increases the efficiency and yield of the three-dimensional heat-conducting structure 200. The precise alignment enabled by the rim 13 contributes to a better thermal conductivity, reducing thermal resistance and optimizing heat transfer between the heat pipe 20 and the vapor chamber 10. In one embodiment, the vapor chamber 10 further includes a capillary structure (not shown) and a cooling fluid (not shown) that are arranged in the interior of the casing 11.

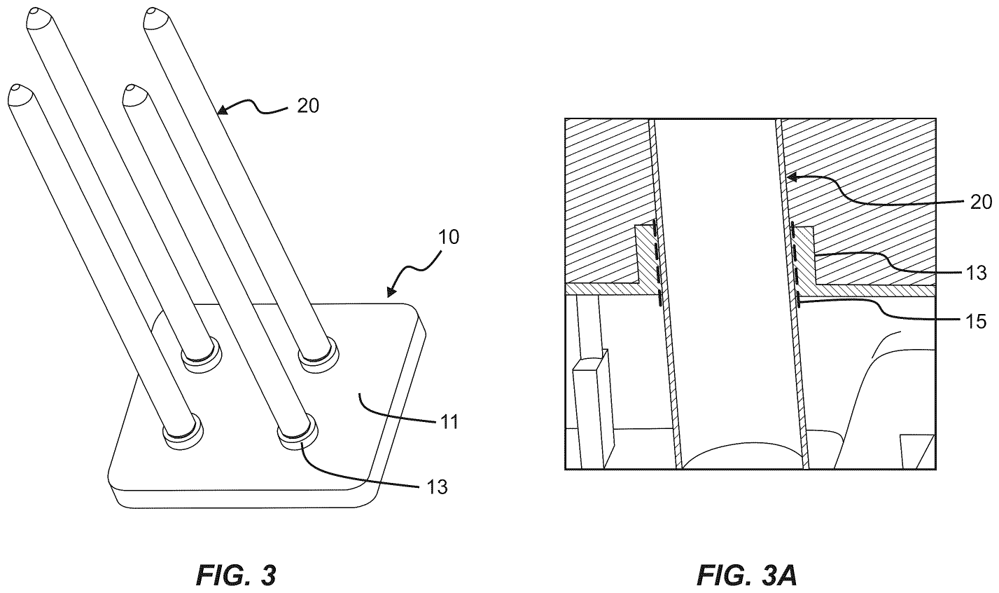

Method 100 proceeds to the step 104, in which the heat pipe 20 is placed into the through hole 12 on the vapor chamber 10 as shown in FIG. 3. The heat pipe 20 in FIG. 3 is a hallow metal pipe. The heat pipe 20 has an open end 21 that is inserted into the through hole 12 and in communication with the interior of the casing 11. In an embodiment, the number of through holes 12 is equal to the number of the heat pipes 20. In FIG. 3A, minor gaps 15 are evident between the heat pipe 20 and the assembly rim 13, as indicated by the dotted lines. If these gaps 15 are not properly sealed, there is a risk that the welded solder may flow into the casing 11 interior. This unwanted infiltration of solder could compromise the structural integrity, reduce thermal efficiency, and lead to system malfunctions. To prevent this, it is important to take appropriate measures to effectively seal the gaps 15, such as applying laser welding.

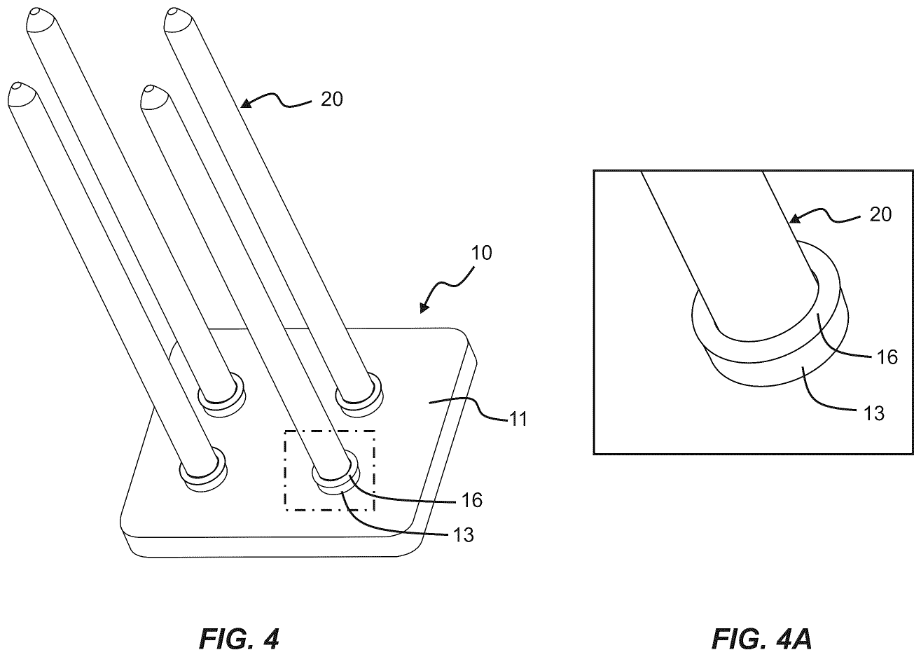

Method 100 proceeds to the step 106, in which laser welding process is applied to the gaps 15 between the heat pipe 20 and the rim 13 as shown in FIG. 4. The gaps 15 between the heat pipe 20 and the rim 13 are sealed as shown in FIG. 4A. During this step, the laser beam is directed precisely at the gaps 15, effectively sealing them to ensure a secure bond 16 between the components. The high precision offered by laser welding allows for the creation of very specific and focused welds, which significantly reduces the possibility of heat spreading to unintended areas. Accordingly, the laser beam does not physically touch or affect any other parts of the heat-conducting structure, focusing solely on the gaps 15 between the heat pipe 20 and the rim 13. This localized application of heat minimizes distortion, ensuring the overall structural integrity and performance of the heat-conducting assembly. Further, the laser welding process creates a strong and durable seal that enhances the thermal efficiency and reliability of the assembly, preventing any unwanted material from entering or disrupting the internal components of the device.

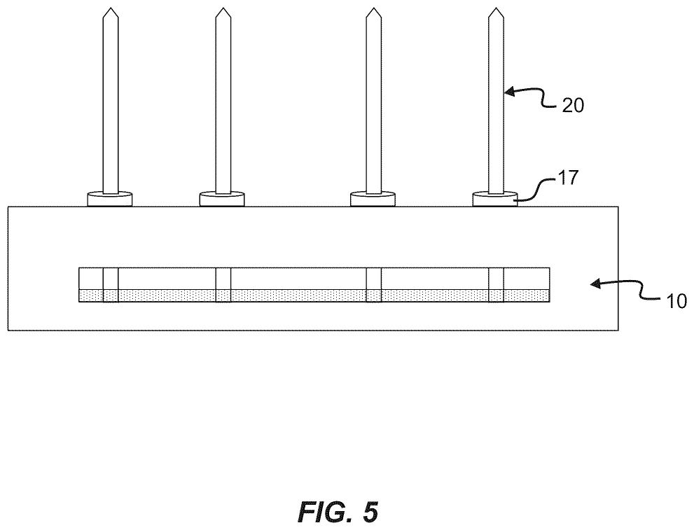

Method 100 process to the step 108, in which a welding ring 17 is placed on a joint position between the heat pipe 20 and the vapor chamber 10, as shown in FIG. 5, which provides a cross-sectional view of the heat conducting structure 200. In FIG. 5, the welding ring 17 is sheathed on an outer surface of the heat pipe 20 and disposed on the casing 11 so that the welding ring 17 encloses the rim 13. The welding ring 17 is positioned above the sealed gaps 15 and is in contact with an outer surface of the rim 13. In one embodiment, the welding ring 17 is primarily made of metal (e.g. copper). However, the embodiment is not limited thereto. In other embodiments, the welding ring 17 can be made of alloy or heat resistant non-metal. In one embodiment, the welding ring 17 is used as a solder. In other embodiments, the solder can also be a welding strip or a welding paste.

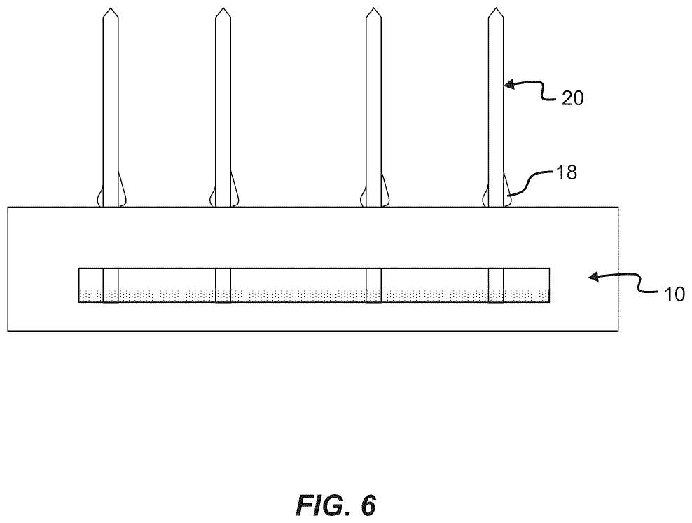

Method 100 process to the step 110, in which a welding process is applied to solder the welding ring 17 to secure the connection between the heat pipe 20 and the vapor chamber 10, as shown in FIG. 6, which provides a cross-sectional view of the heat conducting structure 200. In FIG. 6, the welding ring 17 is soldered to secure the heat pipe 20 onto the vapor chamber 10. Because the laser welding was applied to seal the gaps 15 between the heat pipe 20 and the rim 13 in the previous steps, the soldered welding ring will not overflow to the interior of the vapor chamber 10. By following the described process above, the spaces between the heat pipe 20 and the vapor chamber 10 can be tightly sealed, allowing the heat pipe 20 to conduct heat quickly and uniformly.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. Of course, the disclosed embodiments are merely exemplary embodiments and that various modifications can be made without departing from the spirit and scope of the disclosure. Further, it should be understood that various aspects of the embodiment are not mutually exclusive of each other and can be combined as desired by a person of ordinary skill in the art as a matter of design choices.

The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

What is claimed is:

1. A three-dimensional heat conducting structure, comprising:
a vapor chamber having a casing and at least one through hole that is formed on the casing and is in fluid communication with an interior of the casing;
at least one heat pipe having an open end that is inserted into the through hole and is in fluid communication with the interior of the casing; and
a rim that is disposed on an outer surface of the vapor chamber, wherein
gaps between the rim and the heat pipe are sealed by laser welding, and
a welding ring is soldered to further secure the connection between the heat pipe and the vapor chamber.

2. The three-dimensional heat conducting structure according to claim 1, wherein the vapor chamber further includes a capillary structure and a cooling fluid that are arranged in the interior of the casing.

3. The three-dimensional heat conducting structure according to claim 1, wherein the welding ring is made of metal, alloy or heat-resistant non-metal material.

4. The three-dimensional heat conducting structure according to claim 1, wherein the soldered welding ring stays between the vapor chamber and the heat pipe without overflowing to the interior of the vapor chamber.

5. The three-dimensional heat conducting structure according to claim 1, wherein the welding ring encloses the rim before being soldered.

6. The three-dimensional heat conducting structure according to claim 1, wherein a secure bond is formed between the rim and the heat pipe after the laser welding is applied solely on the gaps between the heat pipe and the rim.

7. The three-dimensional heat conducting structure according to claim 1, wherein the rim is formed around a periphery of the through hole and is protruded from an outer surface of the vapor chamber.

8. The three-dimensional heat conducting structure according to claim 1, wherein the rim is welded to the surface of the vapor chamber, surrounding the periphery of the through hole.

9. A manufacturing method of a three-dimensional heat conducting structure, comprising: forming a vapor chamber that includes a casing with at least one through hole;
forming at least one heat pipe that has an open end, and inserting the open end into the through hole so that the heat pipe and vapor chamber are in fluid communication;
applying laser welding process to gaps between the heat pipe and a rim;
placing a welding ring on a joint position of the heat pipe and the vapor chamber so that the welding ring can enclose the rim; and
applying a welding process to solder the welding ring to secure the connection between the heat pipe and the vapor chamber.

10. The manufacturing method of a three-dimensional heat conducting structure according to claim 9, wherein the rim is formed around a periphery of the through hole and is protruded from an outer surface of the vapor chamber.

11. The manufacturing method of a three-dimensional heat conducting structure according to claim 9, wherein the rim is welded to the surface of the vapor chamber, surrounding the periphery of the through hole.

12. The manufacturing method of a three-dimensional heat conducting structure according to claim 9, wherein the welding ring is sheathed on the heat pipe and disposed on the casing.

13. The manufacturing method of a three-dimensional heat conducting structure according to claim 9, wherein the welding ring encloses the rim before being soldered.

14. The manufacturing method of a three-dimensional heat conducting structure according to claim 9, wherein the vapor chamber further includes a capillary structure and a cooling fluid that are arranged in the interior of the casing.

15. The manufacturing method of a three-dimensional heat conducting structure according to claim 9, wherein the welding ring is made of metal, alloy or heat-resistant non-metal material.

16. The manufacturing method of a three-dimensional heat conducting structure according to claim 9, wherein the soldered welding ring stays between the vapor chamber and the heat pipe without overflowing to the interior of the vapor chamber.

17. The manufacturing method of a three-dimensional heat conducting structure according to claim 9, the laser welding is applied solely on the gaps between the heat pipe and the rim.
